(19) United States
(12) Patent Application Publication
(10) Pub. No.: US 2012/0132368 A1
(43) Pub. Date: May 31, 2012

(54) PLASMA TREATMENT APPARATUS

(75) Inventors: Hiroyuki KOBAYASHI, Kodaira (JP); Takumi TANDOU, Hachioji (JP); Shoichi NAKASHIMA, Hitachi (JP); Naoshi ITABASHI, Hachioji (JP)

(73) Assignee: Hitachi, Ltd.

(21) Appl. No.: 13/292,137

(22) Filed: Nov. 9, 2011

(30) Foreign Application Priority Data
Nov. 30, 2010 (JP) 2010-266420

(51) Int. Cl. H01L 21/3065; B01J 19/08; C23C 16/50

(52) U.S. Cl. 156/345.43; 118/723 E; 422/186.07

(57) ABSTRACT

To improve durability of an electric discharge part of a dielectric barrier discharge system, a plasma treatment apparatus is configured so that a plasma source of a corona discharge system is installed in the vicinity of a plasma source of the dielectric barrier discharge system, a plasma generated by corona discharge is used as an auxiliary plasma, and a discharge sustaining voltage of a main plasma generated by the dielectric barrier discharge is reduced.

### CLAIM OF PRIORITY

The present application claims priority from Japanese patent application JP 2010-266420 filed on Nov. 30, 2010, the content of which is hereby incorporated by reference into this application.

### FIELD OF THE INVENTION

The present invention relates to a plasma treatment apparatus, and more specifically, to a plasma treatment apparatus suitable for performing film formation, reforming, cleaning, sterilization, etc. using a plasma.

### BACKGROUND OF THE INVENTION

In recent years, investigation of technologies of generating plasmas at atmospheric pressure has progressed, which enables generation of functional films such as diamond-like carbon (DLC), organic matter removal on material surfaces, plasma sterilization, reforming of material surfaces, gasses, gas-liquid mixtures, etc. to be examined extensively. In the case where a plasma is generated in a specific extent area or more at atmospheric pressure, dielectric barrier discharge is widely used. The dielectric barrier discharge systems are broadly grouped into two systems. One is a system adopted in a plasma treatment apparatus described in Japanese Unexamined Patent Publication No. 2005-135892, and is of a parallel planar system in which a solid dielectric is inserted between two metal electrode plates arranged in parallel and glow discharge is made to occur in a discharge space by power feeding to the electrode plates. Another one is a system adopted in a plasma treatment apparatus described in Japanese Unexamined Patent Publication No. 2006-331664, for example, in which two comb-shaped electrode are arranged in one plane of the dielectric. This discharge electrode pattern is adopted in the plasma-display panel as a planar discharge system for many years.

### SUMMARY OF THE INVENTION

In dielectric barrier discharge, discharging is performed by applying a high frequency (RF) power with a voltage of not less than several kV.

According to the inventors' investigation, a parallel plate system as described in Japanese Unexamined Patent Publication No. 2005-135892 requires a large RF power to be supplied in order to make glow discharge be generated continuously and stably in a discharge space. By a planar discharge system described in Japanese Unexamined Patent Publication No. 2006-331664, in order to generate the glow discharge continuously and stably on a surface of the dielectric similarly, a large RF electric power needs to be supplied.

On the other hand, the thickness of the dielectric film covering the electrode is generally about 1 mm or less, and naturally it is predicted that it is ablated little by little during electric discharge. If the large RF power is applied, ablation of the dielectric film will become rapid according to it. Since the thickness of the dielectric film is thin, some contrivance is required to extend the life of an electric discharge part. Moreover, there is a case where a discharge voltage is close to a breakdown voltage of the dielectric. In this case, there is a possibility that the dielectric film may be damaged at one burst and some measure is necessary.

The problem to be solved by the present invention is to improve durability of the electric discharge part of the dielectric barrier discharge system in the plasma treatment apparatus.

A typical example of the present invention is shown as follows. The plasma treatment apparatus according to an aspect of the present invention has an auxiliary plasma source that has a first RF power source and a first electrode for electric discharge and generates an auxiliary plasma, and a main plasma source that has a second RF power source and a second electrode for electric discharge and generates a main plasma, and is characterized in that the first electrode of the auxiliary plasma source is disposed in the vicinity of a plasma generation area of the main plasma source, and a frequency of the first RF power source is higher than a frequency of the second RF power source.

According to the aspect of the present invention, since it becomes possible to lower the discharge voltage of the dielectric barrier discharge, it becomes possible to extend the life of the electric discharge part of the plasma treatment apparatus.

### BRIEF DESCRIPTION OF THE DRAWINGS

FIG. 1A is a side view showing a configuration of an electric discharge module of a plasma treatment apparatus that is a first embodiment of the present invention;

FIG. 1B is a plan view showing the configuration of the electric discharge module that is the first embodiment;

FIG. 2A is a diagram for explaining a distance S between an auxiliary plasma PL1 and a main plasma PL2 in the present invention;

FIG. 2B is a diagram showing one example of a relationship between a first RF power source (RFP1) and a second RF power source (RFP2) in the present invention;

FIG. 3A is a diagram for explaining an operation of the electric discharge module in a first embodiment. FIG. 3B is a diagram for explaining an operation of the electric discharge module in the first embodiment;

FIG. 3C is a diagram for explaining an operation of the electric discharge module in the first embodiment;

FIG. 4 is a diagram showing an outline of an electric discharge module of the plasma treatment apparatus that is a second embodiment of the present invention;

FIG. 5A is a plan view showing a configuration of an electric discharge module of the plasma treatment apparatus that is a third embodiment of the present invention;

FIG. 5B is a diagram for explaining an operation of the electric discharge module when seeing from its side face that is the third embodiment;

FIG. 6 is a side view showing a configuration of an electric discharge module of the plasma treatment apparatus that is a fourth embodiment of the present invention;

FIG. 7A is a plan view showing a configuration of a main plasma source of the electric discharge module that is the fourth embodiment;

FIG. 7B is a side view showing a configuration of an auxiliary plasma source of the electric discharge module that is the fourth embodiment;

FIG. 7C is a plan view showing a configuration of the auxiliary plasma source of the electric discharge module that is the fourth embodiment;

FIG. 8A is a diagram for explaining an operation of the electric discharge module in the fourth embodiment;

FIG. 8B is a diagram for explaining an operation of the electric discharge module in the fourth embodiment;

FIG. 9 is a plan view showing an outline of a plasma treatment apparatus that is a fifth embodiment of the present invention;

FIG. 10 is a side view showing an outline of a plasma treatment apparatus that is a sixth embodiment of the present invention; and

FIG. 11 is a side view showing an outline of a plasma treatment apparatus that is a seventh embodiment of the present invention.

### DETAILED DESCRIPTION OF THE PREFERRED EMBODIMENTS

In this embodiment, an electric discharge module that has a main plasma source for generating a main plasma based on dielectric barrier discharge, and an auxiliary plasma source that is driven by a frequency higher than a frequency used for the dielectric barrier discharge in the vicinity of an electric discharge part of the main plasma source and generates the auxiliary plasma by an electric discharge system of the dielectric barrier discharge, corona discharge, or the like is installed. This configuration makes it possible to reduce a voltage required for electric discharge of the main plasma and to extend the life of the electric discharge part of the main plasma source.

According to a typical embodiment of the present invention, the plasma treatment apparatus is configured so that in the vicinity of an electric discharge plate for generating a plasma by means of the dielectric barrier discharge system such that two kinds of electrodes (antenna and earth) are formed inside the one sheet of a dielectric, the electric discharge module of a corona discharge system that performs electric discharge, for example, by applying an RF power to a pair of needle metal electrodes is installed as an auxiliary plasma generating unit, whereby it reduces the plasma maintenance voltage in the dielectric barrier discharge and suppresses ablation of the dielectric film.

Hereafter, embodiments of a plasma discharge module to which the present invention is concretely applied and a plasma treatment apparatus will be described in detail, referring to drawings.

### First Embodiment

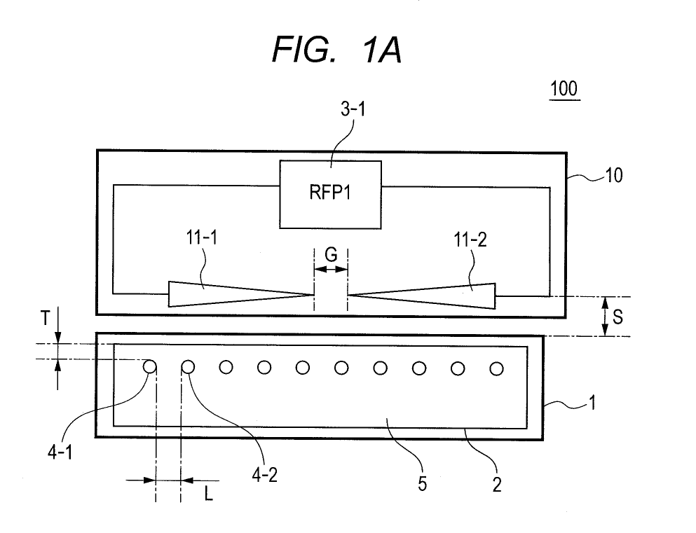

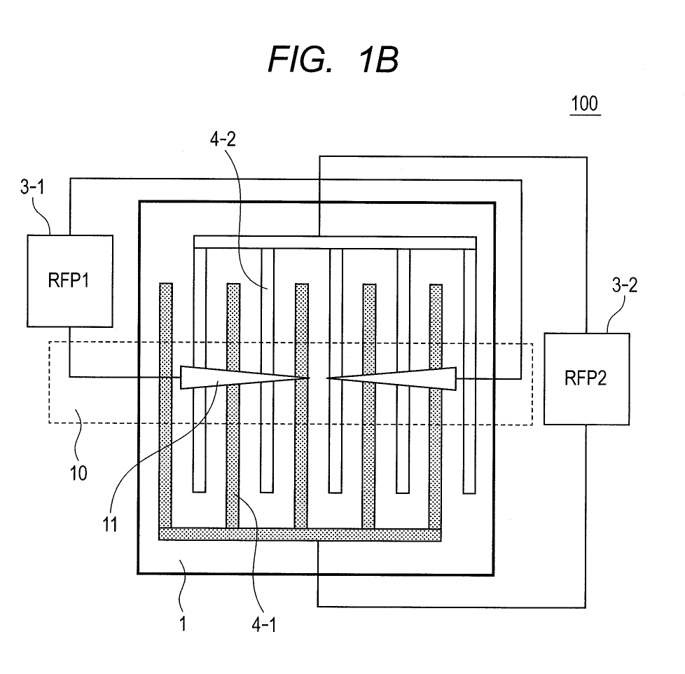

First, a plasma treatment apparatus that is a first embodiment of the present invention will be described, referring to FIG. 1A to FIG. 3C. FIG. 1A shows a diagram of the electric discharge module of the plasma treatment apparatus when seeing it from its side; FIG. 1B is a diagram thereof when seeing it from the above. A planar electric discharge module 100 has a main plasma source 1 and an auxiliary plasma source 10.

In this embodiment, in the vicinity of an electric discharge plate 2 for generating a main plasma by the dielectric barrier discharge system such that two kinds of electrodes (an antenna and a ground) are formed in one sheet of a dielectric, an auxiliary plasma is generated by the corona discharge system that makes electric discharge occurs by applying the RF power to the pair of needle metal electrodes.

That is, the main plasma source 1 is equipped with the electric discharge plate 2 and a second RF power source (RFP2) 3-2. The electric discharge plate 2 has a structure where one pair of mutually isolated comb-shaped electrode (second electrodes) 4-1 and 4-2 each of which has a plurality of teeth arranged alternately in parallel to a plurality of teeth of the other comb-shaped electrode in the inside of a dielectric 5 made of, for example, quartz glass or a ceramic, such as alumina and yttria. The second electrode is connected to the second RF power source 3-2, and generates dielectric barrier discharge (a main plasma PL2) in the vicinity of the surface of the dielectric 5 by the RF power being applied thereto in a state where the electrodes 4-1 and 4-2 have mutually different polarities or one of them is grounded.

The auxiliary plasma source 10 is equipped with a pair of metal electrodes (first electrodes) 11-1 and 11-2 for corona discharge having pointed tips and a first RF power source (RFP1) 3-1. A gap G of the tips of the pair of the metal electrodes is about 1 mm to 2 mm. In the auxiliary plasma source 10, an auxiliary plasma PL1 by the corona discharge is formed in the vicinity of an area at the pointed tips of the first electrode 11. As long as those functions of the first electrode as well as the second electrode are the same, respectively, other shapes may be usable, and it is natural that a shape is not limited to the shape shown in the figure.

Incidentally, the electrodes 4-1, 4-2 of the main plasma source 1 are arranged in the vicinity of a one-sided (an upper side in FIG. 1A) surface of a dielectric layer 5. A distance between the electrodes 4-1 and 4-2, namely, an inter-electrode distance L is 1 mm or less. The dielectric barrier discharge by the main plasma source 1 is generated on a thinner side of the dielectric layer 5 when seeing from the electrodes 4-1, 4-2, namely, on a dielectric barrier discharge surface of an upper side surface of the dielectric layer 5 in FIG. 1A. Denoting the thickness of the dielectric covering the second electrode, namely, a distance between the electrodes 4-1, 4-2 and the dielectric barrier discharge surface of the upper side surface of the dielectric layer 5 by T, it is desirable that T should be about 100 μm to 1 mm. Since the surface of the comb-shaped electrode is covered with the dielectric, charging the dielectric with electric charges makes a potential difference between the electrodes smaller, so that even when a high voltage is applied, it does not cause transition from the dielectric barrier discharge to arc discharge.

Moreover, the distance between two plasmas of the auxiliary plasma PL1 and the main plasma PL2, in other words, a distance S between a center of the pair of electrodes 11-1, 11-2 for corona discharge and the dielectric barrier discharge surface of the upper side surface of the dielectric layer 5 needs to be not more than a predetermined value by which the auxiliary plasma, here more specifically charged particles, such as ions and electrons, and particles in an excitation state can diffuse to a generation area of the main plasma by a sufficient quantity. In other words, the distance S needs to be a value not more than the predetermined value at which transportation of the charged particles etc. is surely performed.

In order to continuously provide a processed fluid, such as air, to the plasma generation area over the electric discharge plate 2 of the electric discharge module 100, the plasma treatment apparatus is equipped with a pump and duct (illustration is abbreviated).

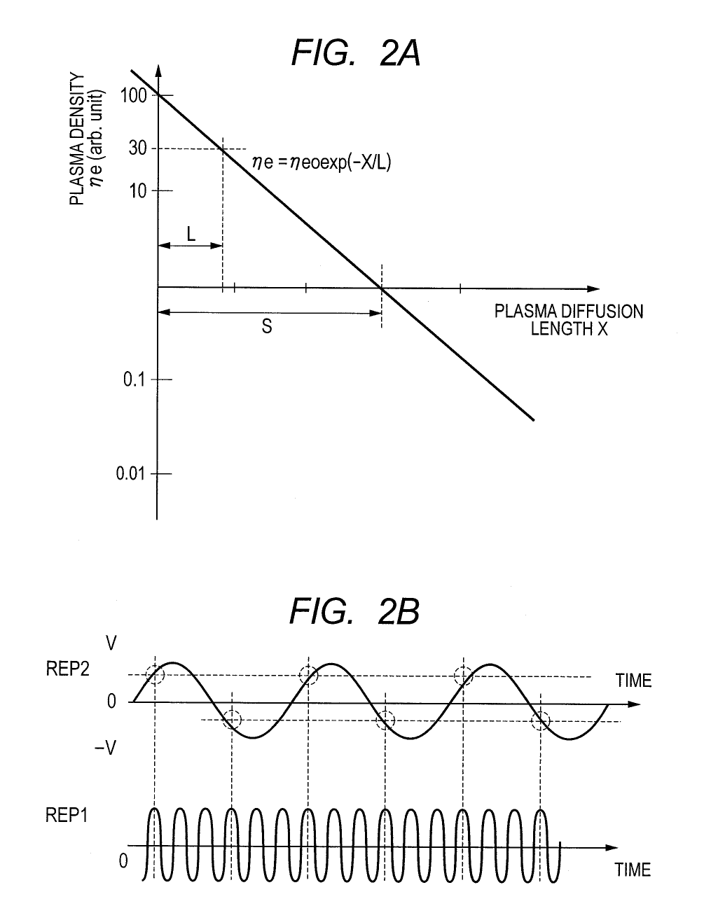

FIG. 2A shows a relationship between a plasma density (electron density: m⁻³) ηₑ in atmosphere and a distance X from the electric discharge part. Denoting the diffusion length of the plasma by L, the distance S reached by a plasma of a density at which assist of the main plasma is expected becomes about 10 L. The distance S becomes 10 mm when the diffusion length L of the plasma is 1 mm. Thus, it is desirable that the distance S between the auxiliary plasma PL1 and the main plasma PL2 should be 10 mm or less. If the distance S falls within this range, the corona discharge will easily ignite the dielectric barrier discharge in the vicinity thereof.

Incidentally, although positions of the pair of electrodes 11-1, 11-2 for corona discharge are in the vicinity of a center of the dielectric barrier discharge surface of the upper side surface of the dielectric layer 5 in FIG. 1A, the positions are not limited to these positions. The positions of the electrodes 11-1, 11-2 may be in a surrounding part as long as they are in the vicinity of the plasma generation area of the main plasma source.

Moreover, although it is desirable that the electric discharge module 100 should be used at atmospheric pressure (about ±10% of the atmospheric pressure) in the present invention, it is also usable even if the pressure atmosphere is 1/10 atmosphere to 2 atmospheres.

Next, a relationship between the first RF power source 3-1 and the second RF power source 3-2 will be described. The auxiliary plasma just needs to be one that can supply charged particles and particles in an excitation state sufficient to be a trigger of a discharge for generating the main plasma PL2, and it is sufficient that its volume be a small amount, i.e., 1/10 or less of a volume of the main plasma PL2. In other words, an electric power of the first RF power source just needs to be 1/10 or less of an electric power of the second RF power source. For example, when the electric power of the second RF power source is 100 W, the electric power of the first RF power source is set to 10 W or less.

On the other hand, seeing the phenomenon with a micro time scale, when the corona discharge has disappeared, if the dielectric barrier discharge is intended to be generated, a possibility that the dielectric barrier discharge causes ignition failure becomes high on that timing. Considering this fact, it is desirable that the auxiliary plasma should be generated almost continuously. Therefore, it is desirable that a frequency f1 of the first RF power source for corona discharge is at least two times higher than (including “two times equal to”) a frequency f2 of the second RF power source for dielectric barrier discharge. As one example, when the frequency f1 of the first RF power source is 10 kHz, the frequency f2 of the second RF power source is set to 100 kHz. As shown in FIG. 2B, when the frequency f1 of the first RF power source (RFP1) is higher than the frequency f2 of the second RF power source (RFP2) for dielectric barrier discharge, at a timing (a circle mark of a dashed line) at which the voltage applied to the electrodes 4-1, 4-2 becomes higher and the dielectric barrier discharge occurs, a state where the voltage of the first RF power source is always high emerges and the corona discharge by it exists, and therefore, charged particles of ions, electrons, etc. and particles in an excitation state by it can be supplied substantially continuously. This lowers a possibility extremely that the dielectric barrier discharge causes ignition failure even when the electric power of the second RF power source is reduced by some degree.

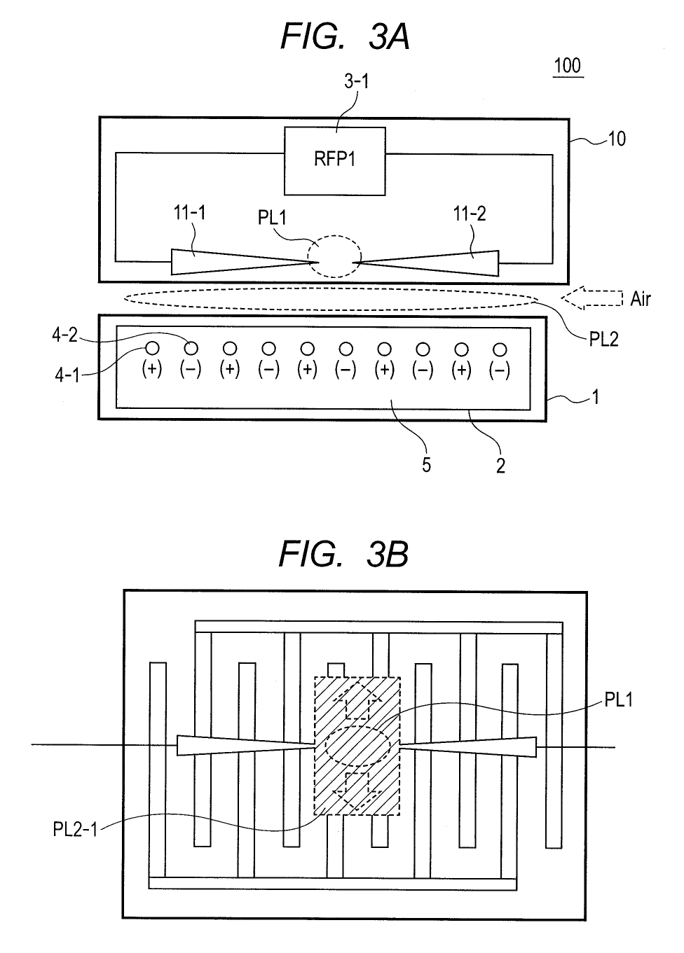

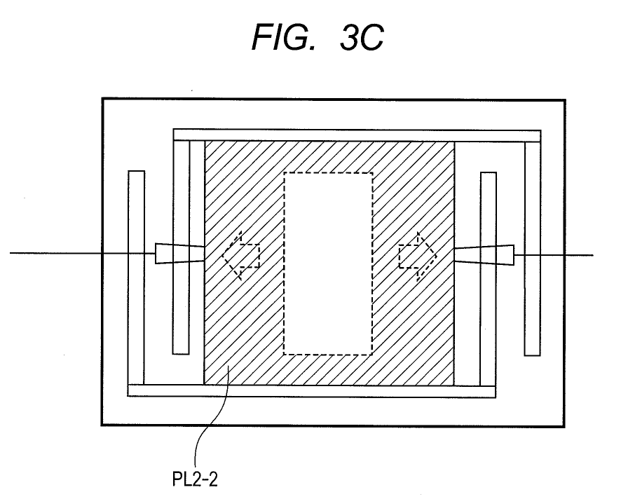

FIGS. 3A to 3C show a relationship between the auxiliary plasma PL1 and the main plasma PL2 that is made to occur by it in the embodiment of the present invention. First, as shown in FIG. 3A, the RF power is applied from the first RF power source, and the auxiliary plasma PL1 is generated by the corona discharge in the plasma source 10. On the other hand, when the RF voltage is applied between the electrodes 4-1, 4-2 from the second RF power source, an electric power of a polarity as shown in the figure is applied to the electrodes 4-1, 4-2 and a dielectric in the vicinity thereof. In this state, as shown in FIG. 3B, the charged particles and the excited particles in the auxiliary plasma PL1 generated by the corona discharge acts on electric charges in the vicinity of the auxiliary plasma PL1, i.e., here between the electrodes 4-1, 4-2 in an area of a central part of the corn-shape electrodes, the dielectric barrier discharge is generated at the position, which generates a main plasma PL2-1. Although in accordance with occurrence of the main plasma PL2-1, charges between the electrodes 4-1, 4-2 in the area of the central part of the comb-shaped electrode are released, the dielectric barrier discharge moves to an intermediate area outside the central part, as shown in FIG. 3C, and a main plasma PL2-2 continues to exist. Then, after the charges in the intermediate area of this comb-shaped electrode were released, the dielectric barrier discharge further occurs between the electrodes 4-1, 4-2 in a surrounding area of the comb-shaped electrode, and the main plasma continues to exist. Thus, being triggered by the charged particles and the excited particles in the auxiliary plasma PL1, the main plasma PL2 occurs in the vicinity of the auxiliary plasma PL1 located at the central part, extends to its surroundings two-dimensionally, and disappears, which phenomenon is repeated. It goes without saying that if the auxiliary plasma PL1 is placed in the surrounding part of the comb-shaped electrode, the dielectric barrier discharge will occur from its vicinity repeatedly.

Generally, in the case where a plasma is generated by using only the plasma source 1 by the dielectric barrier discharge solely, an RF power source whose frequency is a few tens of kHz is used for the second RF power source 3-2 and an applied voltage (Vpp) needs to be a several kV. In this case, the surface of the dielectric layer 5 is ablated little by little by the charged particles (ions) accelerated with a high voltage. When the electrodes 4-1 and 4-2 are exposed by the ablation, the dielectric barrier discharge no longer holds and will move to local arc discharge between the two metal electrodes 4-1, 4-2. In the arc discharge, since a high-density plasma is generated locally and a large current flows, the electrodes and a discharge surface are damaged greatly in a short time. Therefore, a lower discharge voltage V for plasma generation is desirable. Moreover, the applied voltage may cause a breakdown in the inside of the dielectric 5 depending on an applied voltage V, the thickness of the dielectric layer T, or the inter-electrode distance L. The lower the voltage V applied for the electric discharge, the more desirable the process becomes from this viewpoint.

In light of this desire, if the corona discharge is generated as the auxiliary source, namely, a fire in the immediate vicinity of the dielectric barrier discharge surface, for example, at a distance S not more than 10 mm, and the charged particles and the particles in an excitation state are supplied to the dielectric barrier discharge part, it will become possible to reduce the voltage V of the RF power required to generate the main plasma by the dielectric barrier discharge.

Since the corona discharge is an electric discharge between the two metal electrodes 11-1, 11-2, there is no dielectric layer on the surface as in the case of the dielectric barrier discharge, and it seldom needs to consider an influence of the ablation of the electrodes. Moreover, since it is a purpose to generate the auxiliary plasma as a fire, it is not necessary to generate a plasma of a very high density. Moreover, since the auxiliary plasma is used as a fire, there is no necessity to input such a large electric power as accelerates the ablation of the electrodes 4-1, 4-2 into the main plasma source 1.

According to the inventors' experiment, while an RF power of 5 kV is necessary in order to generate a stable plasma only with the main plasma source 1, a combination of the main plasma and the auxiliary plasma enables a sufficiently stable plasma to be generated even with an RF power of 2.5 kV. That is, according to the present invention, compared with the case where the auxiliary plasma is not used in combination with the main plasma, a power of the second RF power source (RFP2), in other words, the applied voltage V of the main plasma source 1 can be reduced to one half or less.

In this way, by using the plasma source by the corona discharge whose durability is high as a discharge assist for a plasma by the dielectric barrier discharge that acts as a main plasma, it is possible to reduce a discharge sustaining voltage of the dielectric barrier discharge part and to thus extend the life of the electric discharge plate 2. As a result, the durability of the whole plasma module 100 can be made high.

As intended uses of the plasma treatment apparatus of this embodiment, the following application is conceivable, for example: as shown in FIG. 3A, a gas, such as air and helium, or a mixed gas as a processed object is supplied along the dielectric barrier discharge surface that is the upper side (surface) of the dielectric layer 5, and this gas or mixed gas is decomposed to generate a plasma, generating ozone, radicals, etc., which performs reforming of the gas, cleaning, sterilization, etc.

Thus, since according to this embodiment, it becomes possible to reduce the discharge voltage of the dielectric barrier discharge, it becomes possible to extend the life of the electric discharge part of the main plasma source, and to make it cheap.

### Second Embodiment

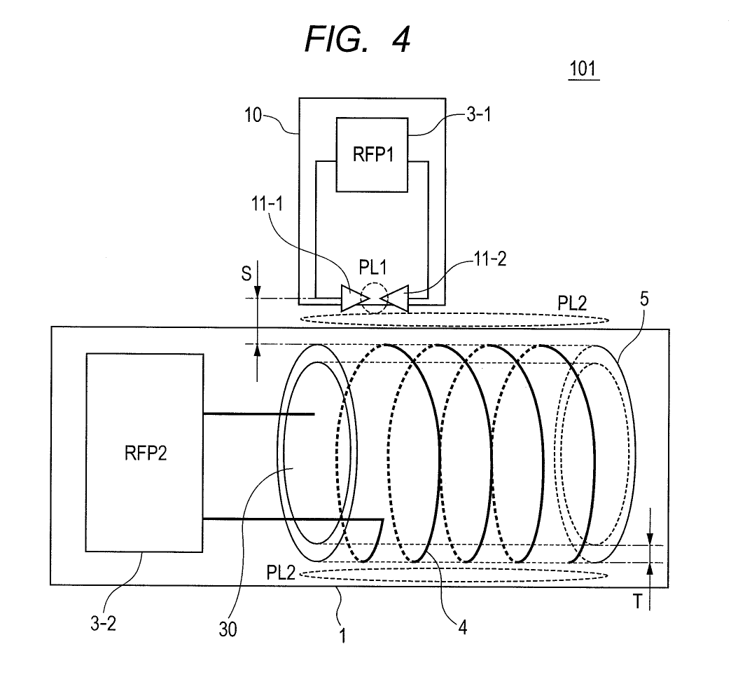

Next, a plasma treatment apparatus that is a second embodiment of the present invention will be explained using FIG. 4. FIG. 4 shows a plasma module 101 of a system for generating main plasma in a cylindrical form (around a cylindrical outer circumference) by the dielectric barrier discharge.

The cylindrical plasma module 101 has the main plasma source 1 based on the dielectric barrier discharge, and the auxiliary plasma source 10 based on the corona discharge.

The auxiliary plasma source 10 is equipped with the pair of metal electrodes (the first electrode) 11 (11-1, 11-2) whose tips are pointed and the first RF power source 3-1 for electric discharge.

In the main plasma source 1, the dielectric layer 5 of thickness T is formed on a surface of a cylindrical metallic substrate electrode. Then, a metallic helical electrode 4 is wound on this dielectric layer 5. A substrate electrode 30 and the helical electrode 4 are connected to the second RF power source 3-2. In this example, the second electrode is comprised of the substrate electrode 30 and the helical electrode 4. By applying an RF power to the substrate electrode 30 and the electrode 4, a plasma is generated along with the electrode 4 and overall the plasma will be generated cylindrically.

In order to reduce the discharge sustaining voltage for plasma generation by the dielectric barrier discharge in the main plasma source 1, the auxiliary plasma source 10 is installed in the vicinity of the main plasma source 1. It is desirable that the distance S between the auxiliary plasma PL1 and the main plasma PL2 should be 10 mm or less, as in the case of the first embodiment. That is, the corona discharge electrode 11 of the auxiliary plasma source 10 is installed at a distance S not more than 10 mm from the dielectric barrier discharge surface. Other conditions are the same as those of the first embodiment. Thereby, the charged particles and the excited particles generated by the corona discharge can be used as a fire for the dielectric barrier discharge for generating the main plasma.

The plasma treatment apparatus of this embodiment can perform film formation, reforming, cleaning, etc. of an inner surface of a cylindrical part that is a processed object, for example, a bearing surface by inserting the dielectric layer 5 of a cylindrical shape of the plasma module 101 into the cylindrical part of the processed object, and generating the main plasma on an outer periphery of the cylinder by the dielectric barrier discharge.

Since according to this embodiment, it becomes possible to reduce the discharge voltage of the dielectric barrier discharge, it becomes possible to extend the life of the electric discharge part of the main plasma source, and to make it cheap.

### Third Embodiment

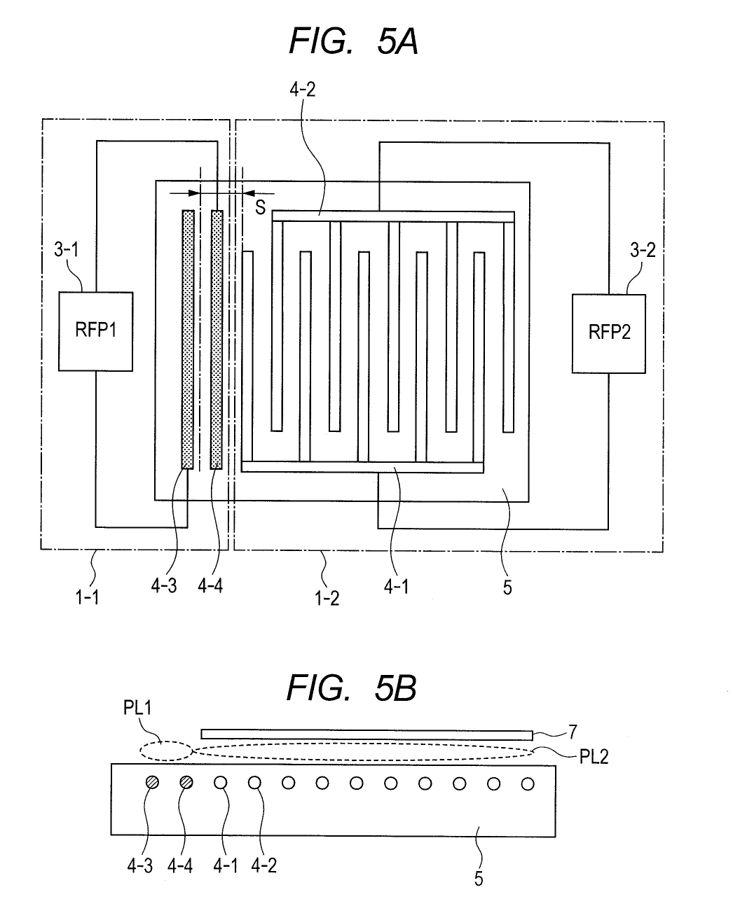

Next, a third embodiment of the present invention will be explained using FIG. 5A and FIG. 5B. FIG. 5A is a plan view showing a configuration of an electric discharge module of the third embodiment; FIG. 5B is an operation explanatory diagram when seeing the electric discharge module of the third embodiment from its side. Explanations of parts of the configuration equivalent to those of the first embodiment are omitted.

In this embodiment, two pairs of electrodes for dielectric barrier discharge are installed in the inside of the common dielectric 5. The electrodes 4-1 and 4-2 are equivalent to the second electrode of the first embodiment, and are connected to the second RF power source 3-2 for electric discharge to generate the main plasma PL2. Electrodes 4-3 and 4-4 are installed on the sides of the electrodes 4-1, 4-2, being equivalent to the first electrode of the first embodiment, and are connected to the first RF power source 3-1. That is, this embodiment has a configuration of having two plasma sources (a first plasma source 1-1 and a second plasma source 1-2) by the dielectric barrier discharge. It is desirable that the distance S between the auxiliary plasma PL1 and the main plasma PL2 should be 10 mm or less, as in the case of the first embodiment. That is, a position of a center of the electrodes 4-3 and 4-4 and a position of an end face of the electrode 4-1 is set to the distance S. Moreover, a volume of the auxiliary plasma PL1 shall be not more than 1/10 of the volume of the main plasma PL2. Other conditions are the same as those of the first embodiment.

The first RF power source is applied to the first plasma source (auxiliary plasma source) 1-1, and performs electric discharge at a frequency higher than that of the second plasma source 1-2. As one example, the first RF power source frequency f1 is set to 100 kHz and the second RF power source frequency f2 is set to 10 kHz. When the frequency of the first RF power source 3-1 is raised, the electrodes 4-3 and 4-4 tend to act as a capacitor, and a larger portion of the applied power passes through the electrodes without being used for electric discharge; therefore, power loss becomes large. On the other hand, since the discharge voltage required for plasma discharge maintenance becomes low, ablation of the dielectric decreases. Therefore, the first plasma source 1-1 is used as the auxiliary plasma source 1-2, namely, a fire for sustaining plasma discharge to the main plasma, and is not used as the main plasma source for performing the plasma treatment. This enables a voltage V required to sustain the electric discharge of the plasma source 1-2 for generating the main plasma for plasma treatment to be lowered and to thus extend the life of the main plasma source. Moreover, the electric discharge part of the main plasma source can be made cheap.

In the plasma treatment apparatus of this embodiment, as shown in FIG. 5B, for example, a processed object 7, such as a semiconductor substrate, is plasma treated by the main plasma PL2 generated by the second (main) plasma source 1-2. The apparatus of this embodiment can perform processings of film formation, reforming of hydrophilic property etc., cleaning such as removal of organic matters, sterilization, or the like on a gas and a solid such as a substrate that are the processed objects.

### Fourth Embodiment

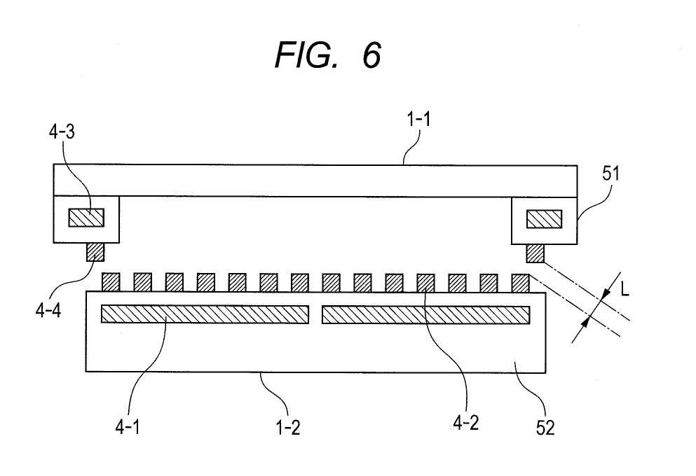

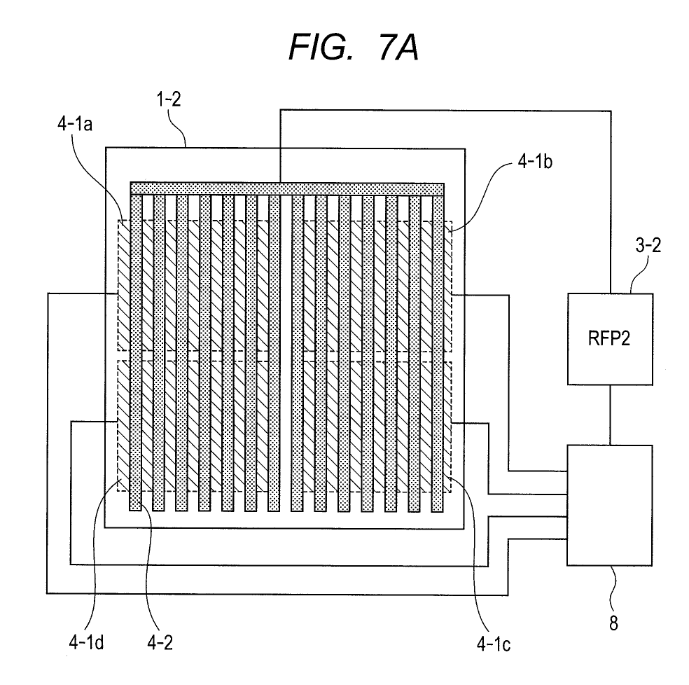

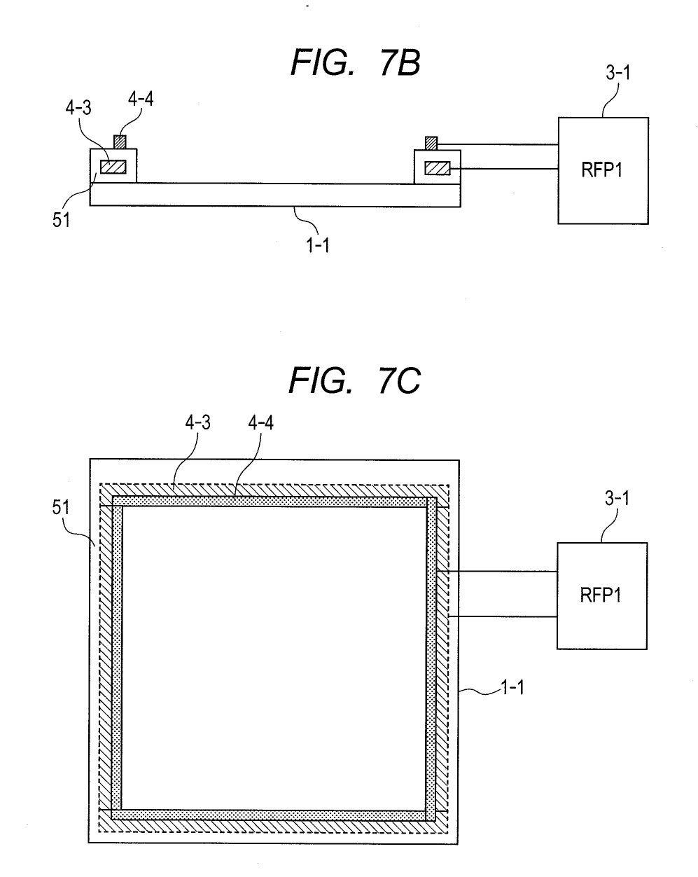

Next, a fourth embodiment of the present invention will be explained using FIG. 6 to FIG. 8B. FIG. 6 is a side view showing a configuration of an electric discharge module of the fourth embodiment. FIG. 7A is a plan view showing a configuration of a main plasma source of the electric discharge module.

In this embodiment, as shown in FIG. 6, it has the first plasma source 1-1 and the second plasma source 1-2. The first plasma source 1-1 is for generating the auxiliary plasma by the dielectric barrier discharge and for lowering a voltage V required to maintain the electric discharge of the main plasma generated by the second plasma source 1-2.

In the main plasma source 1-2, the electrode 4-1 is embedded in a dielectric 52 as a second electrode, and further the comb-shaped electrode 4-2 is installed on the surface of the dielectric 52 on a plasma generation side. The electrode 4-1 is divided into sub-electrodes 4-1a, 4-1b, 4-1c, and 4-1d, which are connected to a power source 3-2 through a power distributor 8. Moreover, the electrode 4-2 is also connected to the power source 3-2. The power distributor 8 can control regarding to which electrode among the sub-electrodes 4-1a to 4-1d the RF power supplied from the power source 3-1 is supplied.

FIG. 7B is a side view showing a configuration of an auxiliary plasma source of the electric discharge module; FIG. 7C is a plan view showing a configuration of the auxiliary plasma source. In the auxiliary plasma source 1-1, the electrode 4-3 is disposed in the inside of the dielectric 51 as the first electrode, the electrode 4-4 is disposed on the surface of the dielectric 51, and the each of them is connected to the RF power source 3-1.

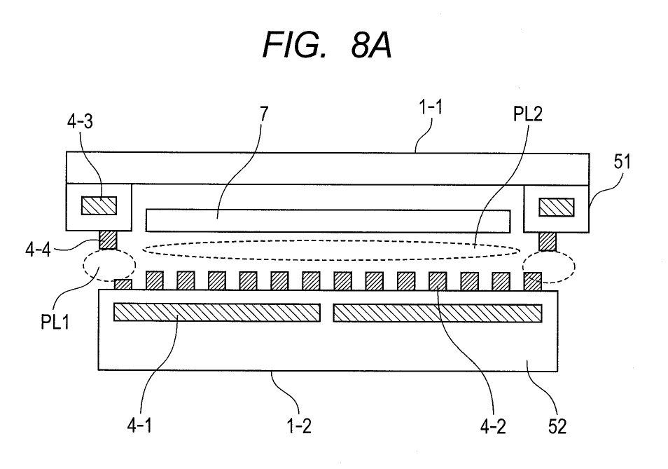

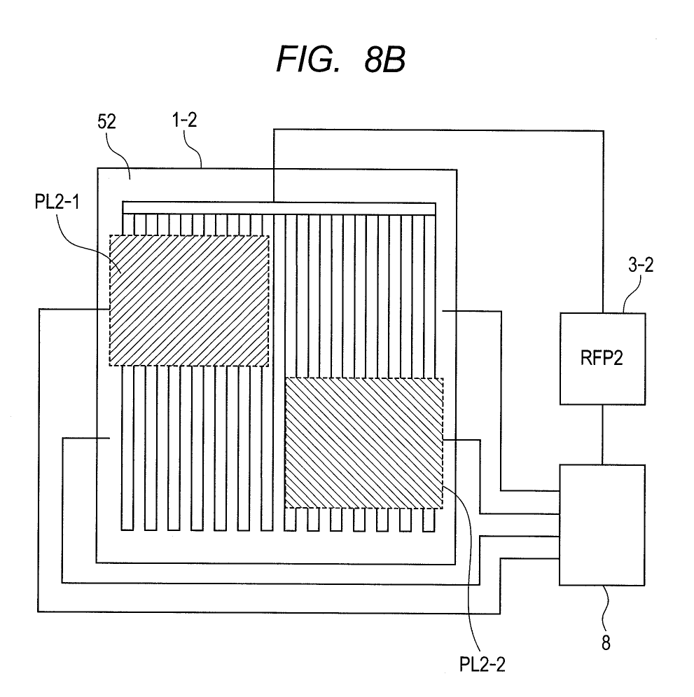

As shown in FIG. 8A, the processed object 7, for example, a substrate, is plasma treated by the main plasma PL2 generated by the second (main) plasma source 1-2. Moreover, as shown in FIG. 8B, the plasma PL2-1 can be generated or the plasma PL2-2 can be generated to the processed object 7. That is, by controlling the RF power to be supplied with the power distributor 8, it is possible to select a portion that should be plasma treated, for example, the main plasma can be generated on all surfaces of the sub-electrodes 4-1a to 4-1d, or the main plasma can be generated only on the sub-electrode 4-1a.

Naturally, it is not necessary to divide the electrode 4-1 into rectangles, and a round shape and a complicated pattern may be usable for division. That is, according to a geometrical shape of the electrode 4-1 disposed in the dielectric, it is possible to create a portion where a plasma is generated and a portion where a plasma is not generated.

Similarly with the each embodiment, the frequency of the first RF power source 3-1 is made higher than the frequency of the second RF power source 3-2, and this setting is for a purpose of generating the auxiliary plasma for reducing the voltage required to maintain the electric charge of the main plasma source 1-2. An effect of this embodiment is the same as that of the third embodiment.

### Fifth Embodiment

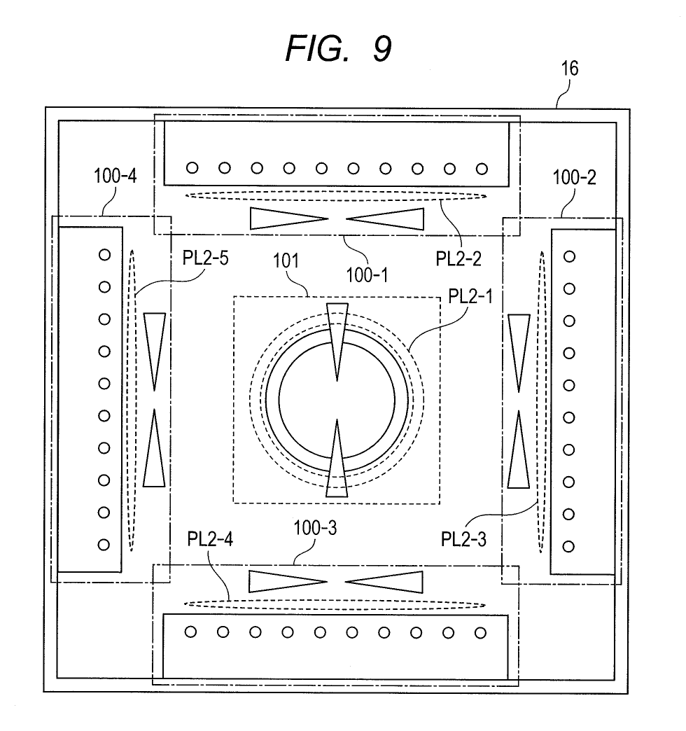

Next, a fifth embodiment of the present invention will be described with reference to FIG. 9. FIG. 9 is a plan view showing an outline of a plasma treatment apparatus that is the fifth embodiment. The plasma treatment apparatus of this embodiment is a plasma treatment apparatus for performing plasma treatment to a processed gas that is a gas or a gas and liquid mixture. On an inner circumference of a duct-shaped enclosure 16 of the plasma treatment apparatus, four planar plasma discharge modules 100 (100-1,100-2,100-3,100-4) are installed. Moreover, in the vicinity of a center of a gas flow path, one cylindrical plasma module 101 shown in the second embodiment is installed. A processing gas is flowing inside the duct-like enclosure 16 in a direction perpendicular to the drawing sheet. Thereby, the main plasmas PL2-1 to PL2-5 are generated at five points in the enclosure 16. It is natural that the number of and arrangement of the electric discharge modules 100 and 101 may be different from the configuration shown in the figure. It is possible to perform a processing of film forming, reforming, cleaning, sterilization, etc. on a single or a plurality of processing objects continuously or in parallel using the main plasmas PL2-1 to PL2-5.

### Sixth Embodiment

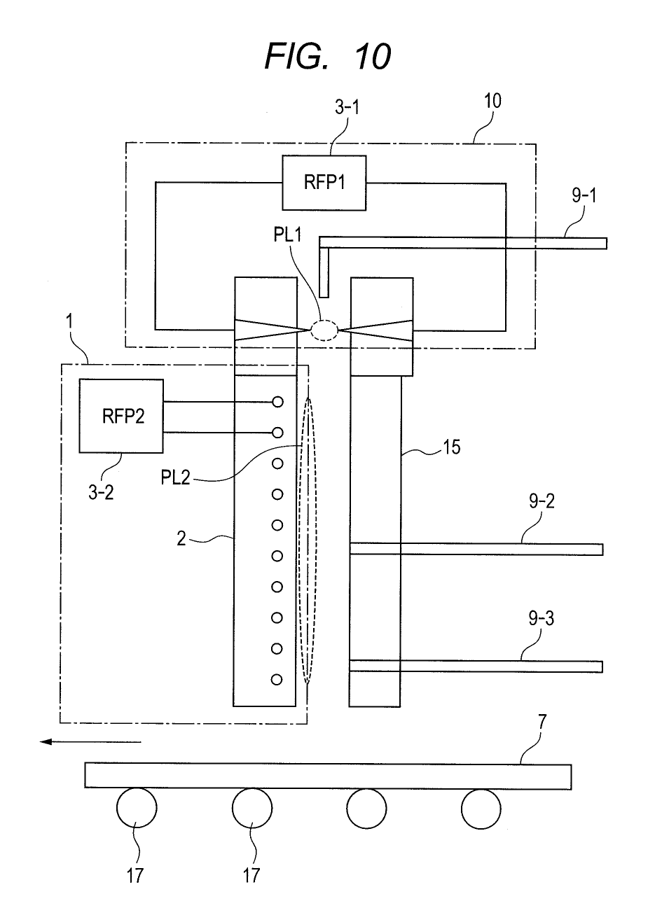

Next, a plasma treatment apparatus of a sixth embodiment of the present invention will be described with reference to FIG. 10. This embodiment is related to a plasma treatment apparatus of a remote plasma system that processes the processed object 7 at a position away from the main plasma. The main plasma source 1 has the same configuration as that of the main plasma source 1 in the dielectric barrier electric discharge module 100 described in the first embodiment and is equipped with the discharge plate 2 and the second RF power source (RFP2) 3-2. Unlike the first embodiment, the electric discharge plate 2 is arranged in a lengthwise direction. In addition, in the vicinity of the main plasma source 1, in this embodiment, above the main plasma source 1, the auxiliary plasma source 10 is installed for the purpose of generating the auxiliary plasma for reducing the voltage required to maintain the electric discharge similarly with the each embodiment. The auxiliary plasma source 10 is equipped with the pair of metal electrodes 11, the first RF power source 3-1 for electric discharge, and a gas supply system 9-1. A planar plate 15 is disposed opposing the electric discharge plate 2 of the main plasma source 1. Gas supply systems 9-2, 9-3 are provided for this planar plate 15, and the processing gas is supplied to a space between the planar plate 15 and the dielectric barrier discharge surface of the electric discharge plate 2. The apparatus is configured so that the processed object 7 is conveyed by a roller 17.

First, by a gas CHx, such as methane, being supplied from the gas supply system 9-1 and the RF power being applied from the first RF power source 3-1 to the pair of metal electrodes 11-1 and 11-2, the auxiliary plasma source 10 of the corona discharge system generates the auxiliary plasma PL1. The auxiliary plasma generated here is transported to the main plasma source 1 for generating main plasma, where gases of methane CHx etc. are decomposed to generate a plasma, namely, the main plasma PL2. Then, the generated main plasma is irradiated to the processed object 7 disposed thereunder, and a predetermined plasma treatment is performed on the surface of the processed object 7 with radicals, ions, and electrons in the main plasma.

Moreover, in the case where a plurality of processing gasses are used, a gas mainly for generating the plasma maybe supplied from the gas supply system 9-1 and other mixed gasses maybe supplied from the planar plate 15 disposed opposing the main plasma source 1, that is, from the gas supply systems 9-2, 9-3.

Since also in this embodiment, it becomes possible to reduce the discharge voltage of the dielectric barrier discharge, it becomes possible to extend the life of the electric discharge part of the main plasma source 1.

### Seventh Embodiment

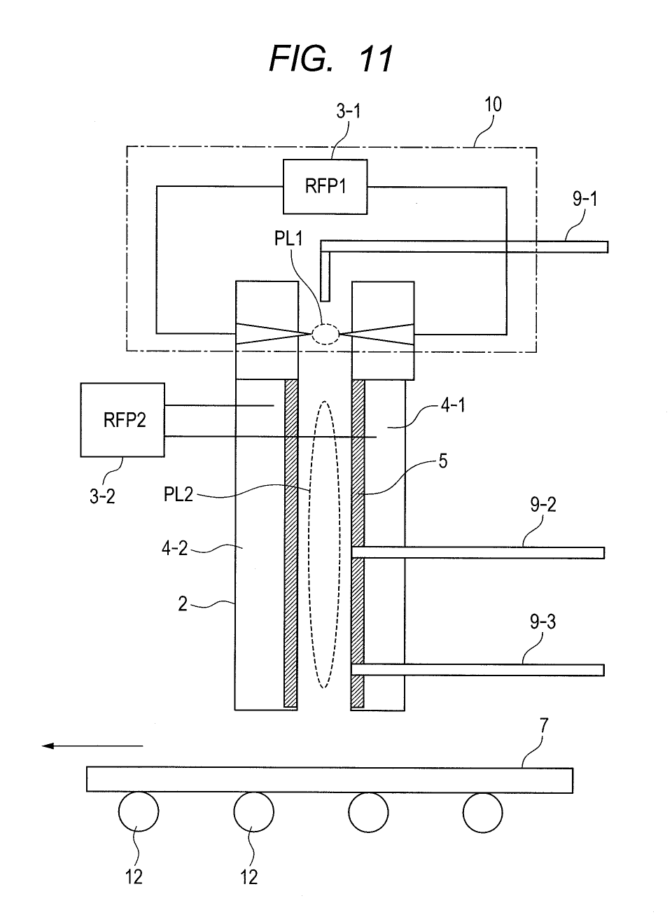

Next, a seventh embodiment of the present invention will be described with reference to FIG. 11. This embodiment adopts a parallel planar discharge electrode for performing the dielectric barrier discharge as the main plasma source 1. That is, the main plasma source 1 for generating main plasma has the parallel planar electrodes 4-1, 4-2 such that the discharge plate 2 made up of a pair of parallel flat plates each having a layer of the dielectric 5 on its surface are arranged opposing each other. The second RF power source (RFP2) is connected to the electrodes 4-1, 4-2. The auxiliary plasma source 10 is installed in the vicinity of the parallel planar electrodes 4-1, 4-5 of the main plasma source 1. As in the case of the first embodiment, a distance between the auxiliary plasma PL1 and the main plasma PL2 is set to 10 mm or less in a shortest part. Other configurations are the same as those of the plasma treatment apparatus of the remote plasma system of the sixth embodiment. The main plasma generated by the main plasma source 1 is irradiated to the processed object 7 placed below it, and a predetermined plasma treatment is performed on the surface of the processed object 7 with radicals, ions, electrons, etc. in the main plasma.

Also in this embodiment, adoption of the auxiliary plasma source 10 has an effect of reducing the voltage required for maintaining an electric discharge in the main plasma generation based on parallel planar dielectric barrier discharge. In addition, as in the case of the third embodiment, the following system may be all right: the system is equipped with two parallel planar dielectric barrier discharge modules, uses one of them as the auxiliary (assist) plasma source, and the other one is used as the main plasma source.

What is claimed is:

1. A plasma treatment apparatus, comprising:
an auxiliary plasma source that has a first high frequency power source and a first electrode for electric discharge and generates an auxiliary plasma;
a main plasma source that has a second high frequency power source and a second electrode for electric discharge and generates a main plasma;
wherein the first electrode of the auxiliary plasma source is disposed in the vicinity of a plasma generation area of the main plasma source, and
a frequency of the first high frequency power source is higher than a frequency of the second high frequency power source.

2. The plasma treatment apparatus according to claim 1,
wherein the main plasma source is equipped with an electric discharge plate having the second electrode and a dielectric film covering the second electrode and performs dielectric barrier discharge.

3. The plasma treatment apparatus according to claim 1,
wherein the auxiliary plasma source is a plasma source of a corona discharge system for generating corona discharge between a pair of opposing electrodes that constitutes the first electrode.

4. The plasma treatment apparatus according to claim 1,
wherein the main plasma source is a plasma source for performing dielectric barrier discharge,
the auxiliary plasma source is a plasma source of a corona discharge system,
the corona discharge always exists at a timing at which the dielectric barrier discharge occurs, and
the auxiliary plasma source continuously supplies charged particles and particles in an excitation state to the main plasma source.

5. The plasma treatment apparatus according to claim 1,
wherein the second electrode has a pair of comb shapes, by covering the second electrode with a dielectric film, a planar electric discharge plate is formed, and in the vicinity of the plasma generation area on the dielectric film covering the second electrode, a pair of opposing electrodes that constitutes a first electrode of the auxiliary plasma source is disposed.

6. The plasma treatment apparatus according to claim 2,
wherein an electric discharge part for the dielectric barrier discharge has a substrate electrode made up of a cylindrical metal, and the substrate electrode is configured so that its surface is coated with a dielectric layer and a helical electrode is wound up on the dielectric layer.

7. The plasma treatment apparatus according to claim 1, comprising a planar electric discharge plate in which two pairs of electrodes are covered with a dielectric film,
wherein the first high frequency power source is connected to one of the pairs of electrodes to constitute the auxiliary plasma source, and
the second high frequency power source is connected to the other of the pairs of electrodes to constitute the main plasma source.

8. The plasma treatment apparatus according to claim 1,
wherein the auxiliary plasma source is equipped with a first electrode comprised of an electrode installed in the inside of a first dielectric and an electrode installed on a surface of the first dielectric as the first electrode,
the main plasma source is equipped with a plurality of planar divided electrodes embedded in a second dielectric and a comb-shaped electrode installed on a surface of the second dielectric, and
the main plasma is generated along a longitudinal shape of the electrode installed in the second dielectric.

9. The plasma treatment apparatus according to claim 8,
comprising an electric power distributor provided between the second high frequency power source and the divided electrodes,
wherein in an electric discharge part of the main plasma source, the plasma generation area is separately controlled manner by the electric power distributor.

10. The plasma treatment apparatus according to claim 1,
wherein an electric discharge part of the main plasma source is configured so that the second electrode is comprised of a pair of opposing planar electric discharge plates covered with a dielectric film and in the vicinity of the plasma generation area of the pair of opposing planar discharge plates, and
a pair of opposing electrodes that constitutes a first electrode of the auxiliary plasma source is disposed.

11. The plasma treatment apparatus according to claim 1,
wherein the plasma generation areas of the auxiliary plasma and the main plasma are at atmospheric pressure.

12. The plasma treatment apparatus according to claim 1,
comprising means for supplying a gas for plasma generation,
wherein the auxiliary plasma source of the corona discharge system is installed on the upstream side of a flow of the gas,
the main plasma source of the dielectric barrier discharge system is installed on the downstream side of the flow of the gas, and
the processed object is disposed on a further downstream side thereof.

13. A plasma treatment apparatus, comprising:
an auxiliary plasma source that has a first high frequency power source and a first electrode for electric discharge and generates an auxiliary plasma; and
a main plasma source that has a second high frequency power source and a second electrode for electric discharge and generates a main plasma;
wherein the first electrode of the auxiliary plasma source is disposed in the vicinity of a plasma generation area of the main plasma source and a volume of the auxiliary plasma is less than or equal to 1/10 of a volume of the main plasma.

14. The plasma treatment apparatus according to claim 13,
wherein a frequency of the first high frequency power source is higher than a frequency of the second high frequency power source, and
electric power of the first high frequency power source is less than or equal to 1/10 of an electric power of the second high frequency power source.

15. The plasma treatment apparatus according to claim 13,
wherein the main plasma source is a plasma source that is equipped with an electric discharge plate having the second electrode and a dielectric film covering the second electrode and performs dielectric barrier discharge, and
the auxiliary plasma source is a plasma source of a corona discharge system for generating corona discharge between a pair of opposing electrodes that constitutes the first electrode.

16. The plasma treatment apparatus according to claim 14,
wherein the plasma generation areas of the auxiliary plasma and the main plasma are at atmospheric pressure, the corona discharge always exists at a timing at which the dielectric barrier discharge occurs, and the auxiliary plasma source continuously supplies charged particles of ions, electrons, etc. and particles in an excitation state to the main plasma source.

17. A plasma treatment apparatus, comprising:
an auxiliary plasma source for generating an auxiliary plasma that has a first high frequency power source and a first electrode for electric discharge; and
a main plasma source for generating a main plasma that has a second high frequency power source and a second electrode for electric discharge;
wherein the first electrode of the auxiliary plasma source is disposed in the vicinity of a plasma generation area of the main plasma source, and
wherein two plasmas of the auxiliary plasma and the main plasma exist at a distance away from each other that enables a sufficient quantity of charged particles and particles in an excitation state generated by the auxiliary plasma to diffuse to the plasma generation area of the main plasma source.

18. The plasma treatment apparatus according to claim 17,
wherein a distance S between the auxiliary plasma and the main plasma is 10 mm or less.

19. The plasma treatment apparatus according to claim 17,
wherein a frequency of the first high frequency power source is higher than a frequency of the second high frequency power source and a volume of the auxiliary plasma is less than or equal to 1/10 of a volume of the main plasma.

20. The plasma treatment apparatus according to claim 17,
wherein the main plasma source is equipped with an electric discharge plate having the second electrode and a dielectric film covering the second electrode, and performs dielectric barrier discharge,
wherein the auxiliary plasma source is a plasma source of a corona discharge system for generating corona discharge between a pair of opposing electrodes that constitute the first electrode,
wherein the corona discharge always exists at a timing at which the dielectric barrier discharge occurs, and
wherein the auxiliary plasma source continuously supplies charged particles and particles in an excitation state caused thereby to the main plasma source.
